(19) United States
(12) Patent Application Publication
(10) Pub. No.: US 2025/0374765 A1
(43) Pub. Date: Dec. 4, 2025

(54) DISPLAY DEVICE AND ELECTRONIC DEVICE INCLUDING THE SAME

(71) Applicant: Samsung Display Co., Ltd., Yongin-si (KR)

(72) Inventors: Hokyun Ahn, Yongin-si (KR); Gunwoo Ko, Yongin-si (KR); Youngmin Kwon, Yongin-si (KR); Junghyun Cho, Yongin-si (KR); Wonhak Choi, Yongin-si (KR)

(21) Appl. No.: 18/963,126

(22) Filed: Nov. 27, 2024

(30) Foreign Application Priority Data
May 31, 2024 (KR) 10-2024-0071790

(51) Int. Cl. H10K 59/122; H10K 59/80

(52) U.S. Cl. CPC H10K 59/122; H10K 59/80515

(57) ABSTRACT

A display device and an electronic device including the same includes: a substrate; an intermediate insulating layer on the substrate and comprising an intermediate opening; a pixel electrode on the intermediate insulating layer such that at least a portion of the pixel electrode is accommodated in the intermediate opening; and a bank layer on the pixel electrode and comprising a pixel opening overlapping the intermediate opening, wherein, in a cross-section taken along a first line extending in a first direction, the intermediate opening and the pixel opening are spaced apart from each other by a first distance, in a cross-section taken along a second line extending in a second direction crossing the first direction, the intermediate opening and the pixel opening are spaced apart from each other by a second distance, and the first distance is different from the second distance.

### CROSS-REFERENCE TO RELATED APPLICATION

The present application claims priority to and the benefit of Korean Patent Application No. 10-2024-0071790, filed on May 31, 2024, in the Korean Intellectual Property Office, the entire disclosure of which is incorporated herein by reference.

### BACKGROUND

### 1. Field

Aspects of one or more embodiments relate to a device.

### 2. Description of the Related Art

Electronic devices based on mobility have been widely used. In addition to small electronic devices such as mobile phones, tablet personal computers (PCs) have been widely used in recent years as mobile electronic devices.

Mobile electronic devices generally include display devices to provide visual information such as static images or moving images to support various functions. In recent years, as other parts for driving the display devices are miniaturized, the proportion of the display devices in electronic devices is gradually increasing, and structures that can be bent to a predetermined angle from a flat state are being developed.

The above information disclosed in this Background section is only for enhancement of understanding of the background and therefore the information discussed in this Background section does not necessarily constitute prior art.

### SUMMARY

Aspects of one or more embodiments relate to a device, and for example, to a display device.

Aspects of some embodiments include a display device configured to meet various brightness characteristics required at the same time by varying a distance between an intermediate opening and a pixel opening in one pixel and an angle of an end of an intermediate insulating layer.

The above aspects are examples and are not limited thereto.

Additional aspects will be set forth in part in the description which follows and, in part, will be apparent from the description, or may be learned by practice of the presented embodiments of the disclosure.

According to one or more embodiments, a display device includes a substrate, an intermediate insulating layer on the substrate and including an intermediate opening, a pixel electrode on the intermediate insulating layer such that at least a portion of the pixel electrode is accommodated in the intermediate opening, and a bank layer on the pixel electrode and including a pixel opening overlapping the intermediate opening, wherein, in a cross-section taken along a first line extending in a first direction, the intermediate opening and the pixel opening are spaced apart from each other by a first distance, in a cross-section taken along a second line extending in a second direction crossing the first direction, the intermediate opening and the pixel opening are spaced apart from each other by a second distance, and the first distance is different from the second distance.

According to one or more embodiments, a distance between the intermediate opening and the pixel opening may change continuously along a circumference of the pixel opening.

According to one or more embodiments, in a plan view, the intermediate opening may include a convex portion.

According to one or more embodiments, in a plan view, the intermediate opening may include a concave portion.

According to one or more embodiments, in a plan view, an end of the intermediate insulating layer defining the intermediate opening may be inclined.

According to one or more embodiments, in a cross-section taken along the first line, the end of the intermediate insulating layer defining the intermediate opening may be inclined by a first angle, in a cross-section taken along the second line, the end of the intermediate insulating layer defining the intermediate opening may be inclined by a second angle, and the first angle may be different from the second angle.

According to one or more embodiments, the second distance may be greater than the first distance, and the first angle may be greater than the second angle.

According to one or more embodiments, in a plan view, an angle between the first line and the second line may be 45 degrees.

According to one or more embodiments, in a plan view, an angle between the first line and the second line may be 90 degrees.

According to one or more embodiments, the display device further includes an emission layer on the bank layer to be accommodated in the pixel opening and a common electrode on the bank layer to cover the emission layer.

According to one or more embodiments, an electronic device includes a substrate, an intermediate insulating layer on the substrate and including an intermediate opening, a pixel electrode on the intermediate insulating layer such that at least a portion of the pixel electrode is arranged in the intermediate opening, and a bank layer on the pixel electrode and including a pixel opening overlapping the intermediate opening, wherein, in a cross-section taken along the first line extending in a first direction, an end of the intermediate insulating layer defining the intermediate opening is inclined by a first angle, in a cross-section taken along the second line extending in a second direction crossing the first direction, the end of the intermediate insulating layer defining the intermediate opening is inclined by a second angle, and the first angle is different from the second angle.

According to one or more embodiments, in a cross-section taken along the first line, the intermediate opening and the pixel opening may be spaced apart from each other by a first distance, in a cross-section taken along the second line, the intermediate opening and the pixel opening may be spaced apart from each other by a second distance, and the first distance may be different from the second distance.

According to one or more embodiments, a distance between the intermediate opening and the pixel opening may change continuously along a circumference of the pixel opening.

According to one or more embodiments, in a plan view, the intermediate opening may include a convex portion.

According to one or more embodiments, the intermediate opening may include a concave portion.

According to one or more embodiments, the second distance may be greater than the first distance, and the first angle may be greater than the second angle.

According to one or more embodiments, in a plan view, an angle between the first line and the second line may be 45 degrees.

According to one or more embodiments, in a plan view, an angle between the first line and the second line may be 90 degrees.

According to one or more embodiments, the display device further includes an emission layer on the bank layer to be accommodated in the pixel opening and a common electrode on the bank layer to cover the emission layer.

According to one or more embodiments, a width of the intermediate opening may be greater than a width of the pixel opening.

Other aspects, features, and characteristics may become more clear from the following drawings, the claims, and the detailed description of the disclosure.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic plan view of a display device according to some embodiments;

FIGS. 2 and 3 are equivalent circuit diagrams of pixels according to some embodiments;

FIG. 4 is a schematic plan view of a display device according to some embodiments;

FIG. 5 is a schematic cross-sectional view of a display device according to some embodiments;

FIG. 6 is a graph showing a brightness measured according to a first separation distance from a front of the display device;

FIG. 7 is a graph showing a brightness measured according to a first separation distance from a side of the display device;

FIG. 8 is a graph showing a brightness measured according to a first intermediate angle from a front of the display device;

FIG. 9 is a graph showing a brightness measured according to a first intermediate angle from a side of the display device;

FIG. 10 is a schematic plan view of the display device according to some embodiments; and

FIG. 11 is a schematic plan view of the display device according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

Because the disclosure may have diverse modified embodiments, some embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

One or more embodiments of the disclosure will be described below in more detail with reference to the accompanying drawings. Those elements that are the same or are in correspondence are rendered the same reference numeral regardless of the figure number, and redundant descriptions thereof are omitted.

In the embodiments, the terms “first” and “second” are not used in a limited sense and are used to distinguish one component from another component.

As used herein, the singular expressions “a,” “an,” and “the” are intended to include the plural forms as well, unless the context clearly indicates otherwise.

It will be understood that the terms “comprises” and/or “comprising” used herein specify the presence of stated features or components, but do not preclude the presence or addition of one or more other features or components.

In the embodiments below, it will be understood that when a layer, region, or element is referred to as being formed “on” another layer, area, or element, it can be directly or indirectly formed on the other layer, region, or element. That is, for example, intervening layers, regions, or elements may be present.

In the drawings, for convenience of description, sizes of components may be exaggerated or reduced. In other words, because sizes and thicknesses of elements in the drawings are arbitrarily illustrated for convenience of description, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

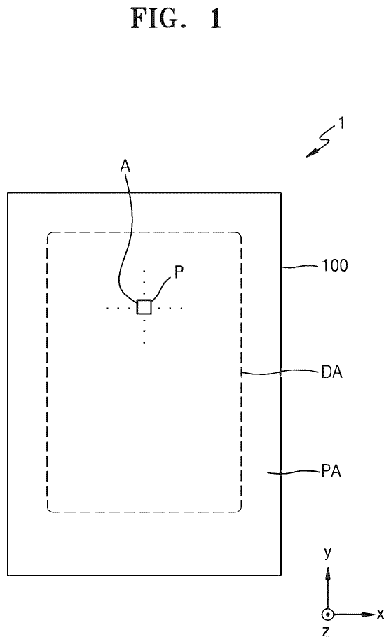

FIG. 1 is a schematic plan view of a display device 1 according to some embodiments.

Referring to FIG. 1, the display device 1 may include a display area DA and a peripheral area PA, which is a non-display area. The display area DA includes pixels P including organic light-emitting diodes OLED to provide a certain image. The peripheral area PA, which does not display images, includes a scan driver and a data driver that are configured to provide electrical signals to be applied to the pixels P of the display area DA and includes power lines configured to provide power such as a driving voltage or a common voltage. Although FIG. 1 shows a single pixel P, as a person having ordinary skill in the art would appreciate, the display device 1 may include any number of pixels P according to the design and size of the display device 1.

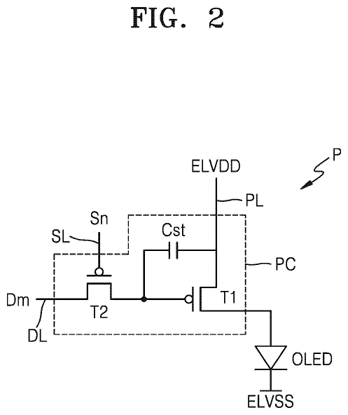

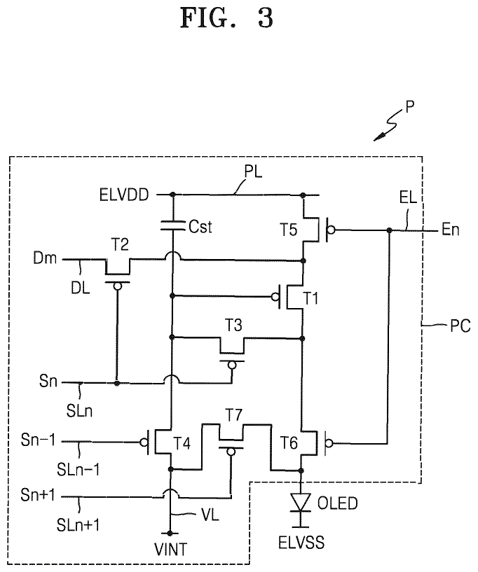

FIGS. 2 and 3 are equivalent circuit diagrams of the pixels P according to the present embodiments.

Referring to FIG. 2, each pixel P includes a pixel circuit PC connected to a scan line SL and a data line DL, and an organic light-emitting diode OLED connected to the pixel circuit PC.

The pixel circuit PC may include a driving thin film transistor T1, a switching thin film transistor T2, and a storage capacitor Cst. The switching thin film transistor T2 is connected to the scan line SL and the data line DL, and transmits, in response to a scan signal Sn input through the scan line SL, a data signal Dm input through the data line DL to the driving thin film transistor T1.

The storage capacitor Cst is connected to the switching thin film transistor T2 and a driving voltage line PL, and is configured to store a voltage corresponding to the difference between a voltage received from the switching thin film transistor T2 and a driving voltage ELVDD supplied to the driving voltage line PL.

The driving thin film transistor T1 is connected to the driving voltage line PL and the storage capacitor Cst, and may control a driving current flowing in the organic light-emitting diode OLED through the driving voltage line PL corresponding to a value of the voltage stored in the storage capacitor Cst. The organic light-emitting diode OLED may emit light having a certain brightness according to the driving current. Although FIG. 2 illustrates various components in a pixel circuit PC, embodiments according to the present disclosure are not limited thereto, and according to various embodiments, the pixel circuit PC may include additional components without departing from the spirit and scope of embodiments according to the present disclosure.

Although FIG. 2 illustrates that the pixel P includes two thin film transistors and one storage capacitor, the disclosure is not limited thereto.

Referring to FIG. 3, the pixel circuit PC may include driving and switching thin film transistors T1 and T2, a compensation thin film transistor T3, a first initialization thin film transistor T4, a first emission control thin film transistor T5, a second emission control thin film transistor T6, and a second initialization thin film transistor T7.

The drain electrode of the driving thin film transistor T1 may be electrically connected to the organic light-emitting diode OLED via the second emission control thin film transistor T6. The driving transistor T1 may be configured to receive a data signal Dm and supply the driving current to the organic light-emitting diode OLED according to a switching operation of the switching thin film transistor T2.

The gate electrode of the switching thin film transistor T2 is connected to the scan line SL and the source electrode is connected to the data line DL. The drain electrode of the switching thin film transistor T2 may be connected to the source electrode of the driving thin film transistor T1 and may be connected to the driving voltage line PL via the first emission control thin film transistor T5.

The switching thin film transistor T2 may perform a switching operation in which the switching thin film transistor T2 is turned on according to the scan signal Sn received through the scan line SL and is configured to transmit the data signal Dm transmitted to the data line DL to the source electrode of the driving thin film transistor T1.

The gate electrode of the compensation thin film transistor T3 may be connected to the scan line SLn. The source electrode of the compensation thin film transistor T3 may be connected to the drain electrode of the driving thin film transistor T1 and may be connected to the pixel electrode of the organic light-emitting diode OLED via the second emission control thin film transistor T6. The drain electrode of the compensation thin film transistor T3 may be connected to any one electrode of the storage capacitor Cst, the source electrode of the first initialization thin film transistor T4, and the gate electrode of the driving thin film transistor T1. The compensation thin film transistor T3 may be turned on according to the scan signal Sn received through the scan line SL to connect the gate electrode and the drain electrode of the driving thin film transistor T1 to each other to diode-connect the driving thin film transistor T1.

The gate electrode of the first initialization thin film transistor T4 may be connected to a second scan line SLn−1. The drain electrode of the first initialization thin film transistor T4 may be connected to an initialization voltage line VL. The source electrode of the first initialization thin film transistor T4 may be connected to any one electrode of the storage capacitor Cst, the drain electrode of the compensation thin film transistor T3, and the gate electrode of the driving thin film transistor T1. The first initialization thin film transistor T4 may be turned on according to a second scan signal Sn−1 received through the second scan line SLn−1 and perform an initialization operation for transmitting an initialization voltage VINT to the gate electrode of the driving thin film transistor T1 and initializing the voltage of the gate electrode of the driving thin film transistor T1.

The gate electrode of the first emission control transistor T5 may be connected to an emission control line EL. The source electrode of the first emission control thin film transistor T5 may be connected to the driving voltage line PL. The drain electrode of the first emission control thin film transistor T5 is connected to the source electrode of the driving thin film transistor T1 and the drain electrode of the switching thin film transistor T2.

The gate electrode of the second emission control transistor T6 may be connected to the emission control line EL. The source electrode of the second emission control thin film transistor T6 may be connected to the drain electrode of the driving thin film transistor T1 and the source electrode of the compensation thin film transistor T3. The drain electrode of the second emission control thin film transistor T6 may be electrically connected to the pixel electrode of the organic light-emitting diode OLED. The first emission control thin film transistor T5 and the second emission control thin film transistor T6 may be simultaneously turned on according to an emission control signal En received through the emission control line EL, and thus, the driving voltage ELVDD is transmitted to the organic light-emitting diode OLED and the driving current flows in the organic light-emitting diode OLED.

The gate electrode of the second initialization thin film transistor T7 may be connected to a third scan line SLn+1. The source electrode of the second initialization thin film transistor T7 may be connected to the pixel electrode of the organic light-emitting diode OLED. The drain electrode of the second initialization thin film transistor T7 may be connected to the initialization voltage line VL. The second initialization thin film transistor T7 may be turned on according to a third scan signal Sn+1 received through the third scan line SLn+1, thereby initializing the pixel electrode of the organic light-emitting diode OLED.

The other electrode of the storage capacitor Cst may be connected to the driving voltage line PL. Any one electrode of the storage capacitor Cst may be connected to the gate electrode of the driving thin film transistor T1, the drain electrode of the compensation thin film transistor T3, and the source electrode of the first initialization thin film transistor T4.

The relative electrode of the organic light-emitting diode OLED may be supplied with a common power voltage ELVSS. The organic light-emitting diode OLED may receive a driving current from the driving thin film transistor T1 and emit light.

The number of thin film transistors and storage capacitors and the circuit design of the pixel circuit PC is not limited to those illustrated in FIGS. 2 and 3, and may be variously modified. Although FIG. 3 illustrates various components in a pixel circuit PC, embodiments according to the present disclosure are not limited thereto, and according to various embodiments, the pixel circuit PC may include additional components or fewer components without departing from the spirit and scope of embodiments according to the present disclosure.

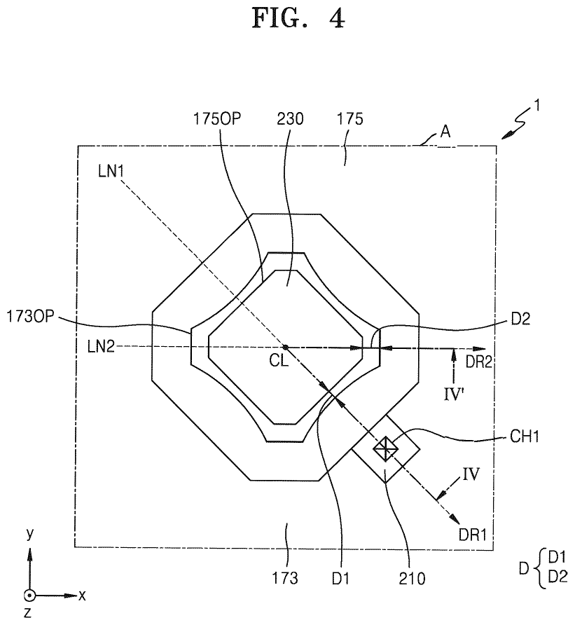

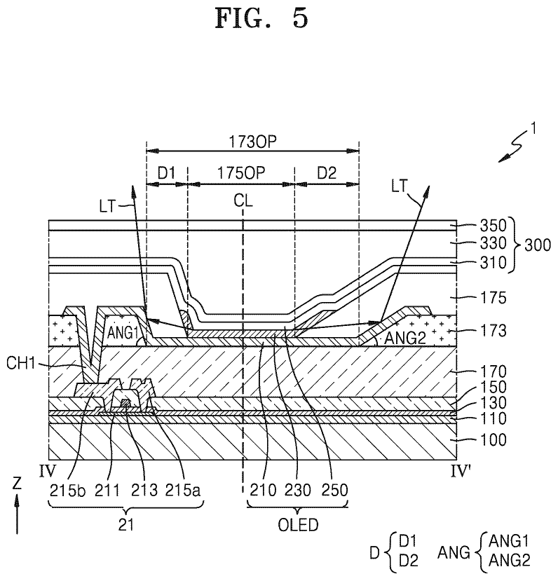

FIG. 4 is a schematic plan view of the display device 1 according to some embodiments, and FIG. 5 is a schematic cross-sectional view of the display device 1 according to some embodiments.

Particularly, FIG. 4 is an enlarged view of portion A of FIG. 1, and FIG. 5 is a cross-sectional view of the display device 1 of FIG. 4 taken along the line IV-IV′.

Referring to FIGS. 4 and 5, the display device 1 may include a substrate 100, the organic light-emitting diode OLED, a buffer layer 110, a gate insulating layer 130, an interlayer insulating layer 150, a planarization layer 170, an intermediate insulating layer 173, a bank layer 175, and an encapsulation layer 300.

The substrate 100 may include any of various flexible or bendable materials. For example, the substrate 100 may include a polymer resin such as polyethersulfone (PES), polyacrylate, polyetherimide (PEI), polyethylene naphthalate (PEN), polyethylene terephthalate (PET), polyphenylene sulfide (PPS), polyarylate (PAR), polyimide (PI), polycarbonate (PC), or cellulose acetate propionate (CAP). However, the substrate 100 may have a multi-layer structure including two layers and a barrier layer therebetween. Each of the two layers may include polymer resin, and the barrier layer may include an inorganic material, such as silicon oxide, silicon nitride, or silicon oxynitride. However, various modifications thereto may be made. Furthermore, when the substrate 100 is not bent, the substrate 100 may be formed of glass or the like.

The organic light-emitting diode OLED is located on the substrate 100, and a pixel circuit is arranged between the substrate 100 and the organic light-emitting diode OLED and electrically connected to the organic light-emitting diode OLED to control the degree of brightness of the organic light-emitting diode OLED. FIG. 5 shows an example of a first thin film transistor 21 that may be included in the pixel circuit.

As shown in FIG. 5, the first thin film transistor 21 may include a semiconductor layer 211 including amorphous silicon, polycrystalline silicon, or an organic semiconductor material, a gate electrode 213, a source electrode 215a, and a drain electrode 215b. FIG. 5 illustrates that the first thin film transistor 21 includes the source electrode 215a and the drain electrode 215b, but the disclosure is not limited thereto.

For example, the source electrode 215a and/or the drain electrode 215b may be a portion of a wiring. Alternatively, the first thin film transistor 21 may not include the source electrode 215a and/or the drain electrode 215b, and a source area of the semiconductor layer 211 may act as the source electrode or a drain area of the semiconductor layer 211 may act as the drain electrode. For example, the first thin film transistor 21 may not include the source electrode 215a, and the source area of the semiconductor layer 211 of the first thin film transistor 21 may be integrally formed with the drain area of another thin film transistor. In this case, although the first thin film transistor 21 may not include the source electrode and the other thin film transistor may not include the drain electrode, the drain electrode of the other thin film transistor may be electrically connected to the source electrode of the first thin film transistor 21 in the pixel circuit diagram. This applies to embodiments and modifications thereof described below in the same manner.

To secure insulation between the semiconductor layer 211 and the gate electrode 213, the gate insulating layer 130 including silicon oxide, silicon nitride, and/or silicon oxynitride may be arranged between the semiconductor layer 211 and the gate electrode 213.

The interlayer insulating layer 150 including an inorganic material such as silicon oxide, silicon nitride, and/or silicon oxynitride may be located on the upper portion of the gate electrode 213, and the source electrode 215a and the drain electrode 215b may be located on the interlayer insulating layer 150. As such, the insulating layer including an inorganic material may be formed through chemical vapor deposition (CVD) or atomic layer deposition (ALD). This applies to embodiments and modifications thereof described below in the same manner.

The buffer layer 110 including an inorganic material such as silicon oxide, silicon nitride, and/or silicon oxynitride may be arranged between the first thin film transistor 21 and the substrate 100. The buffer layer 110 may planarize a top surface of the substrate 100 or may prevent, reduce, or minimize contaminants or impurities from the substrate 100 or the like from penetrating the semiconductor layer 211 of the first thin film transistor 21.

The gate electrode 213 may be formed of a metal such as molybdenum or aluminum, and may be formed by a sputtering method. The gate electrode 213 may have a single or multi-layer structure. For example, the gate electrode 213 may have a two-layer structure of Mo/Al.

Each of the source electrode 215a and the drain electrode 215b may include a metal such as titanium or aluminum, and may have a single or multi-layer structure. For example, each of the source electrode 215a and the drain electrode 215b may have a three-layer structure including Ti/Al/Ti.

The planarization layer 170 may be located on the first thin film transistor 21. For example, as shown in FIG. 5, when the organic light-emitting diode OLED is located on the first thin film transistor 21, the planarization layer 170 may generally planarize the upper portion of the first thin film transistor 21. The planarization layer 170 may include an organic material such as acryl, benzocyclobutene (BCB), or hexamethyldisiloxane (HMDSO). Although the planarization layer 170 has a single-layer structure in FIG. 5, various modifications may be made. For example, the planarization layer 170 may have a multi-layer structure.

In the display area DA (refer to FIG. 1) of the substrate 100, the organic light-emitting diode OLED may be located on the planarization layer 170. The organic light-emitting diode OLED may include a pixel electrode 210, a common electrode 250, and an intermediate layer 230 between the pixel electrode 210 and the common electrode 250 and including an emission layer.

The pixel electrode 210 is electrically connected to the first thin film transistor 21 by contacting one of the source electrode 215a and the drain electrode 215b through a first contact hole CH1 formed in the planarization layer 170 or the like, as shown in FIG. 5. The pixel electrode 210 may include a transmissive conductive layer including a transmissive conductive oxide, such as ITO, In₂O₃, IZO, or the like, and a reflective layer including a metal, such as Al, Ag, or the like. For example, the pixel electrode 210 may have a three-layer structure including ITO/Ag/ITO.

The bank layer 175 may be located on the planarization layer 170. The bank layer 175 is located on the pixel electrode 210 and may include a pixel opening 175OP overlapping an intermediate opening 173OP. The bank layer 175 defines a pixel by having the pixel opening 175OP exposing the central portion of the pixel electrode 210. Also, as shown in FIG. 5, the bank layer 175 may increase a distance between an edge of the pixel electrode 210 and a common electrode 250 on the pixel electrode 210, thereby preventing or reducing instances of an arc occurring on the edge of the pixel electrode 210. The bank layer 175 may include an organic material such as polyimide or hexamethyldisiloxane (HMDSO).

The intermediate insulating layer 173 may be arranged between the substrate 100 and the bank layer 175, in particular, between the planarization layer 170 and the bank layer 175. Similar to the bank layer 175 including the pixel opening 175OP, the intermediate insulating layer 173 may include the intermediate opening 173OP. That is, the intermediate insulating layer 173 may be located on the substrate 100 and may include the intermediate opening 173OP. The width of the intermediate opening 173OP may be greater than the width of the pixel opening 175OP. When viewed from a direction (e.g., a z-axis direction) perpendicular to the substrate 100 shown in FIG. 4, that is, in a plan view, the area of the intermediate opening 173OP may be greater than the area of the pixel opening 175OP. That is, in a plan view, the pixel opening 175OP may be arranged in the intermediate opening 173OP.

The pixel electrode 210 described above may be located on the intermediate insulating layer 173. At least a portion of the pixel electrode 210 may be accommodated in the intermediate opening 173OP. That is, the edge of the pixel electrode 210 may be located on the intermediate insulating layer 173. In addition, a portion of the pixel electrode 210 may be located on the inner side of the intermediate opening 173OP, that is, an inclined portion, as shown in FIG. 5. In addition, as described above, because the area of the intermediate opening 173OP of the intermediate insulating layer 173 is greater than the area of the pixel opening 175OP of the bank layer 175, the bank layer 175 may cover a portion of the pixel electrode 210 located on the inner side of the intermediate opening 173OP.

The pixel electrode 210 is electrically connected to the first thin film transistor 21 by contacting one of the source electrode 215a and the drain electrode 215b through the first contact hole CH1 formed in the planarization layer 170 or the like, as shown in FIG. 5. Because the intermediate insulating layer 173 is located between the planarization layer 170 and the bank layer 175, the first contact hole CH1 may be formed in the intermediate insulating layer 173 as well as the planarization layer 170. The pixel electrode 210 may be electrically connected to the first thin film transistor 21 through the first contact hole CH1.

The intermediate layer 230 including the emission layer may be located on the bank layer 175 such that the intermediate layer 230 is accommodated in the pixel opening 175OP. The intermediate layer 230 of the organic light-emitting diode OLED may include a low molecular weight material or a high molecular weight material. When the intermediate layer 230 includes a low molecular weight material, the intermediate layer 230 may have a single or multi-layer structure in which a hole injection layer (HIL), a hole transport layer (HTL), an emission layer, an electron transport layer (ETL), and an electron injection layer (EIL) are stacked, and may be formed by using vacuum deposition. When the intermediate layer 230 includes a high molecular weight material, the intermediate layer 230 may have a structure including an HTL and an emission layer. In this case, the HTL may include poly(3,4-ethylenedioxythiophene) (PEDOT), and the emission layer may include a polymer material such as a polyphenylene vinylene (PPV)-based material or a polyfluorene-based material. The intermediate layer 230 may be formed by using screen printing, inkjet printing, laser induced thermal imaging (LITI), or the like.

However, the intermediate layer 230 is not necessarily limited thereto and may have any of various structures. The emission layer of the intermediate layer 230 may have a structure corresponding to the pixel electrode 210, but layers excluding the emission layer of the intermediate layer 230 may be formed integrally with each other across the pixel electrode 210 and other pixel electrodes. The intermediate layer 230 may contact the pixel electrode 210 through a first pixel opening 175OP of the bank layer 175.

The common electrode 250 may be located in the display area DA (refer to FIG. 1) in which the plurality of organic light-emitting diodes OLED are arranged. The common electrode 250 may be located on the bank layer 175 to cover the intermediate layer 230 including the emission layer. In the above structure, the common electrode 250, the intermediate layer 230, and the pixel electrode 210 may be electrically connected to each other. The common electrode 250 may include a transmissive conductive layer formed of ITO, In₂O₃, or IZO, and may include a semi-transmissive layer including a metal such as Al or Ag. For example, the common electrode 250 may include a semi-transmissive layer including MgAg.

The encapsulation layer 300 may be located on the common electrode 250. The encapsulation layer 300 may include at least one inorganic layer and at least one organic layer. For example, the encapsulation layer 300 may include a first inorganic encapsulation layer 310, an organic encapsulation layer 330, and a second inorganic encapsulation layer 350 that are sequentially stacked, but is not limited thereto and may have various structures.

The first inorganic encapsulation layer 310 and the second inorganic encapsulation layer 350 may include at least one material selected from a group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride (SiON).

The organic encapsulation layer 330 may include at least one material selected from a group consisting of an acrylic resin layer, a methacrylic resin layer, polyisoprene, a vinyl-based resin layer, an epoxy-based resin layer, an urethane-based resin layer, a cellulosic resin layer, and a perylene-based resin layer.

According to some embodiments, various functional layers such as polarizing layers, color filter layers, touch screen layers, etc. may further be located on the encapsulation layer 300.

The emission layer of the organic light-emitting diode OLED may generate light from excitons formed in the emission layer by holes supplied from the pixel electrode 210 and electrons supplied from the common electrode 250. Some light formed in the emission layer may travel along a front portion (e.g., a +z direction) of the display device 1, pass through the common electrode 250 and the encapsulation layer 300, and be extracted to the outside, and some other light may travel along the pixel electrode 210 direction (e.g., a −z direction), be reflected on the pixel electrode 210, travel along the front portion (e.g., the +z direction) of the display device 1, pass through the common electrode 250 and the encapsulation layer 300, and be extracted to the outside.

Some other light formed in the emission layer may travel along a lateral direction. FIG. 5 shows an example of a travel path of light LT traveling along the lateral direction. Regarding the display device 1 according to some embodiments, as described above, a portion of the pixel electrode 210 may be located on the inner side of the intermediate opening 173OP, which is an inclined portion. Therefore, light LT traveling along a side direction from the emission layer may be reflected in a portion of the pixel electrode 210 located on the inner side of the intermediate opening 173OP, which is an inclined portion, as shown in FIG. 5, and then, may travel along the front (e.g., the +z-axis direction) of the display device 1.

In a plan view shown in FIG. 4, with respect to a center line CL (e.g., a line extending in the z-axis direction), a first line LN1 extending in a first direction DR1 and a second line LN2 extending in a second direction DR2 may be defined. That is, the center line CL, the first line LN1, and the second line LN2 may cross each other.

In the cross-section shown in FIG. 5, the left portion with respect to the center line CL may be a cross-section of the display device 1 taken along the first line LN1, and the right portion with respect to the center line CL may be a cross-section of the display device 1 taken along the second line LN2.

In the cross-section of the display device 1 taken along the first line LN1, the intermediate opening 173OP and the pixel opening 175OP may be spaced apart from each other by a first distance D1. That is, in a cross-section of the display device 1 taken along the first line LN1, the first distance D1 may be a distance between an end of the intermediate insulating layer 173 defining the intermediate opening 173OP and an end of the bank layer 175 defining the pixel opening 175OP.

In the cross-section of the display device 1 taken along the second line LN2, the intermediate opening 173OP and the pixel opening 175OP may be spaced apart from each other by a second distance D2. That is, in a cross-section of the display device 1 taken along the second line LN2, the second distance D2 may be a distance between the end of the intermediate insulating layer 173 defining the intermediate opening 173OP and the end of the bank layer 175 defining the pixel opening 175OP. In this case, the first distance D1 may be different from the second distance D2. For example, the second distance D2 may be greater than the first distance D1.

A distance between the intermediate opening 173OP and the pixel opening 175OP may be defined as a first separation distance D. In a plan view shown in FIG. 4, the first separation distance D between the intermediate opening 173OP and the pixel opening 175OP may be changed continuously along a circumference of the pixel opening 175OP. In a plan view, the second distance D2, which is the first separation distance D along the second line LN2, may be greater than the first distance D1, which is the first separation distance D along the first line LN1. In this case, in a plan view, the first separation distance D may include continuously increasing sections from the first distance D1 to the second distance D2, along the circumference of the pixel opening 175OP.

In this case, in a plan view, the intermediate opening 173OP may include a concave portion. That is, in a plan view, at least a portion of the intermediate opening 173OP may be concave with respect to a direction moving radially away from the center line CL. The end of the intermediate insulating layer 173 defining the intermediate opening 173OP may include a convex portion. That is, in a plan view, with respect to a direction toward the center line CL from the outside, at least a portion of the end of the intermediate insulating layer 173 may be convex.

As shown in FIG. 4, in a plan view, the pixel opening 175OP may have a rectangular shape. In this case, the edge of the pixel opening 175OP may be chamfered and/or rounded. In a plan view, an angle between the first line LN1 and the second line LN2 may be 45 degrees. For example, in a plan view, the first line LN1 may penetrate the center of a side of the pixel opening 175OP. In a plan view, the second line LN2 may penetrate through a vertex of the pixel opening 175OP. In this case, the vertex of the pixel opening 175OP may be chamfered and/or rounded.

In a cross-sectional view, the end of the intermediate insulating layer 173, which defines the intermediate opening 173OP, may be inclined. An inclination of the end of the intermediate insulating layer 173 defining the intermediate opening 173OP is defined as a first intermediate angle ANG.

In a cross-section of the display device 1 taken along the first line LN1, the end of the intermediate insulating layer 173 defining the intermediate opening 173OP may be inclined by a first angle ANG1. That is, in a cross-section of the display device taken along the first line LN1, the first intermediate angle ANG may be the first angle ANG1. In a cross-section of the display device 1 taken along the second line LN2, the end of the intermediate insulating layer 173 defining the intermediate opening 173OP may be inclined by a second angle ANG2. That is, in a cross-section of the display device 1 taken along the second line LN2, the first intermediate angle ANG may be the second angle ANG2. Each of the first angle ANG1 and the second angle ANG2 may be an acute angle. Each of the first angle ANG1 and the second angle ANG2 may be 0 degrees or more and 90 degrees or less. In this case, the first angle ANG1 may be different from the second angle ANG2. For example, the first angle ANG1 may be greater than the second angle ANG2. In a plan view shown in FIG. 4, the first intermediate angle ANG may change continuously along the circumference of the pixel opening 175OP.

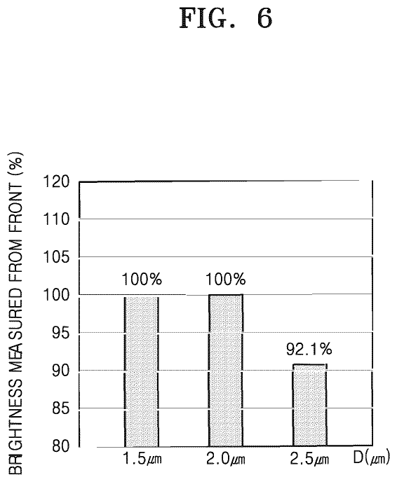

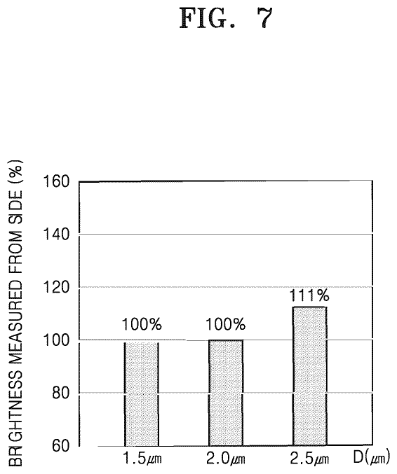

FIG. 6 is a graph showing a brightness measured according to the first separation distance D from the front and FIG. 7 is a graph showing a brightness measured according to the first separation distance D from the side.

In FIG. 6, the horizontal axis represents the first separation distance D and the unit is μm. In addition, in FIG. 6, the vertical axis represents the brightness measured from the front and the unit is %. Particularly, in FIG. 6, the vertical axis defines the brightness measured from the front as 100% when the first separation distance D is 1.5 μm.

In FIG. 7, the horizontal axis represents the first separation distance D and the unit is μm. In addition, in FIG. 7, the vertical axis represents the brightness measured from the side and the unit is %. Particularly, in FIG. 7, the vertical axis defines the brightness measured at a 45 degree-angle with respect to the front as 100% when the first separation distance D is 1.5 μm.

Referring to FIG. 6, when the first separation distance D is 1.5 μm, the brightness measured from the front is 100%, when the first separation distance D is 2.0 μm, the brightness measured from the front is 100%, and when the first separation distance D is 2.5 μm, the brightness measured from the front is 92.1%. In other words, as the first separation distance D increases, the brightness measured from the front is relatively reduced.

Referring to FIG. 7, when the first separation distance D is 1.5 μm, the brightness measured from the side is 100%, when the first separation distance D is 2.0 μm, the brightness measured from the side is 100%, and when the first separation distance D is 2.5 μm, the brightness measured from the side is 111%. In other words, as the first separation distance D increases, the brightness measured from the side is increased.

In summary, when the first separation distance D increases, the brightness measured from the front is relatively reduced and the brightness measured from the side is increased. That is, the brightnesses each measured according to the first separation distance D from the front and from the side may have a trade-off relationship with each other.

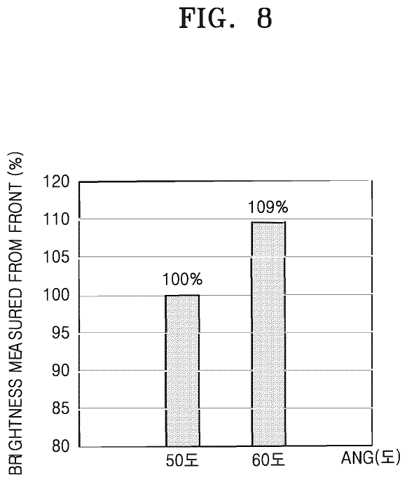

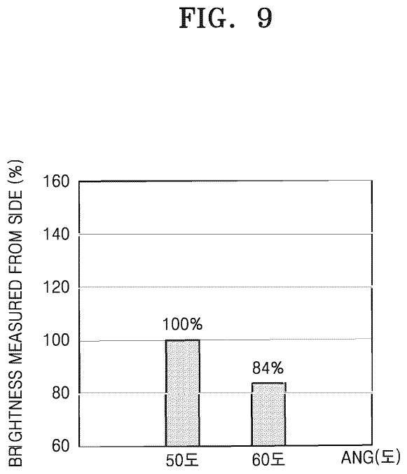

FIG. 8 is a graph showing a brightness measured according to the first intermediate angle ANG from the front and FIG. 9 is a graph showing a brightness measured according to the first intermediate angle ANG from the side.

In FIG. 8, the horizontal axis represents the first intermediate angle ANG and the unit is a degree. In addition, in FIG. 8, the vertical axis represents the brightness measured from the front and the unit is %. Particularly, in FIG. 8, the vertical axis defines the brightness measured from the front as 100% when the first intermediate angle ANG is 50 degrees.

In FIG. 9, the horizontal axis represents the first intermediate angle ANG and the unit is a degree. In addition, in FIG. 9, the vertical axis represents the brightness measured from the side and the unit is %. Particularly, in FIG. 9, the vertical axis defines the brightness measured at a 45 degree-angle with respect to the front as 100% when the first intermediate angle ANG is 50 degrees.

Referring to FIG. 8, the brightness measured from the front is 100% when the first intermediate angle ANG is 50 degrees and the brightness measured from the front is 109% when the first intermediate angle ANG is 60 degrees. In other words, as the first intermediate angle ANG increases, the brightness measured from the front is increased.

Referring to FIG. 9, the brightness measured from the side is 100% when the first intermediate angle ANG is 50 degrees and the brightness measured from the side is 84% when the first intermediate angle ANG is 60 degrees. In other words, as the first intermediate angle ANG increases, the brightness measured from the side is increased.

In summary, when the first intermediate angle ANG increases, the brightness measured from the front is increased and the brightness measured from the side is relatively reduced. That is, the brightnesses each measured according to the first intermediate angle ANG from the front and from the side may have a trade-off relationship with each other.

Referring to FIGS. 4 and 5 again, the second distance D2 may be greater than the first distance D1 and the first angle ANG1 may be greater than the second angle ANG2. That is, a second separation distance of a cross-section of the display device 1 taken along the second line LN2 may be greater than the first separation distance D of a cross-section of the display device 1 taken along the first line LN1. In addition, the first intermediate angle ANG of the cross-section of the display device 1 taken along the first line LN1 may be greater than a second intermediate angle of the cross-section of the display device 1 taken along the second line LN2.

Thus, the brightness measured from the front in a portion adjacent to the first line LN1 may be greater than the brightness measured from the front in a portion adjacent to the second line LN2. In addition, the brightness measured from the side in a portion adjacent to the first line LN1 may be greater than the brightness measured from the side in a portion adjacent to the second line LN2.

According to some embodiments, in one pixel, the first line LN1 may be arranged in a portion in which a high brightness from the front is required and the second line LN2 may be arranged in a portion in which a high brightness from the side is required. That is, the first line LN1 and the second line LN2 may be arranged according to the required brightness characteristics to relatively improve the emission efficiency of the display device 1.

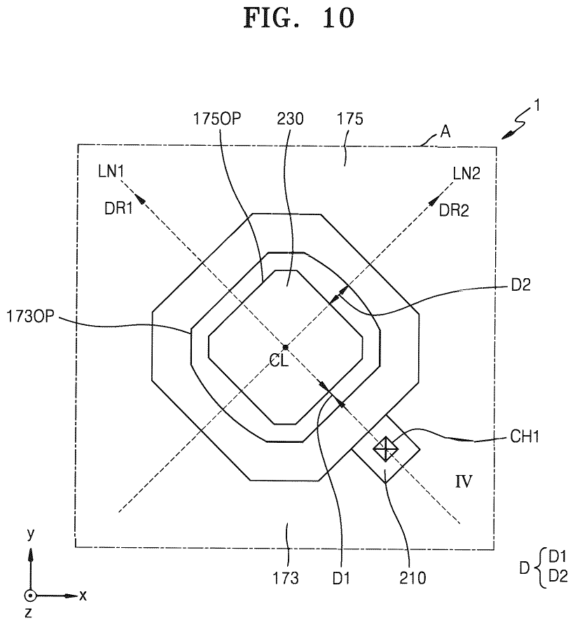

FIG. 10 is a schematic plan view of the display device 1 according to some embodiments.

Particularly, FIG. 10 is an enlarged view of the region A of FIG. 1.

In FIG. 10, the reference numbers that are the same as those of FIGS. 4 and 5 refer to the same members, and thus are omitted.

As shown in FIG. 10, in a plan view, the pixel opening 175OP may have a rectangular shape. In this case, the edge of the pixel opening 175OP may be chamfered and/or rounded. In a plan view, an angle between the first line LN1 and the second line LN2 may be 90 degrees. For example, in a plan view, the first line LN1 may penetrate the center of a side of the pixel opening 175OP. In a plan view, the second line LN2 may penetrate through a center of a side of the pixel opening 175OP.

In the cross-section of the display device 1 taken along the first line LN1, the intermediate opening 173OP and the pixel opening 175OP may be spaced apart from each other by a first distance D1. That is, in a cross-section of the display device 1 taken along the first line LN1, the first distance D1 may be a distance between the end of the intermediate insulating layer 173 defining the intermediate opening 173OP and the end of the bank layer 175 defining the pixel opening 175OP.

In the cross-section of the display device 1 taken along the second line LN2, the intermediate opening 173OP and the pixel opening 175OP may be spaced apart from each other by the second distance D2. That is, in the cross-section of the display device 1 taken along the second line LN2, the second distance D2 may be a distance between the end of the intermediate insulating layer 173 defining the intermediate opening 173OP and the end of the bank layer 175 defining the pixel opening 175OP. In this case, the first distance D1 may be different from the second distance D2. For example, the second distance D2 may be greater than the first distance D1.

The distance between the intermediate opening 173OP and the pixel opening 175OP may be defined as the first separation distance D. In a plan view shown in FIG. 10, the first separation distance D between the intermediate opening 173OP and the pixel opening 175OP may be changed continuously along the circumference of the pixel opening 175OP. In a plan view, the second distance D2, which is the first separation distance D along the second line LN2, may be greater than the first distance D1, which is the first separation distance D along the first line LN1. In this case, in a plan view, the first separation distance D may include continuously increasing sections from the first distance D1 to the second distance D2, along the circumference of the pixel opening 175OP.

In this case, in a plan view, the intermediate opening 173OP may include a convex portion. That is, in a plan view, at least a portion of the intermediate opening 173OP may be convex with respect to a direction moving radially away from the center line CL. The end of the intermediate insulating layer 173 defining the intermediate opening 173OP may include a concave portion. That is, in a plan view, with respect to a direction toward the center line CL from the outside, at least a portion of the end of the intermediate insulating layer 173 may be concave.

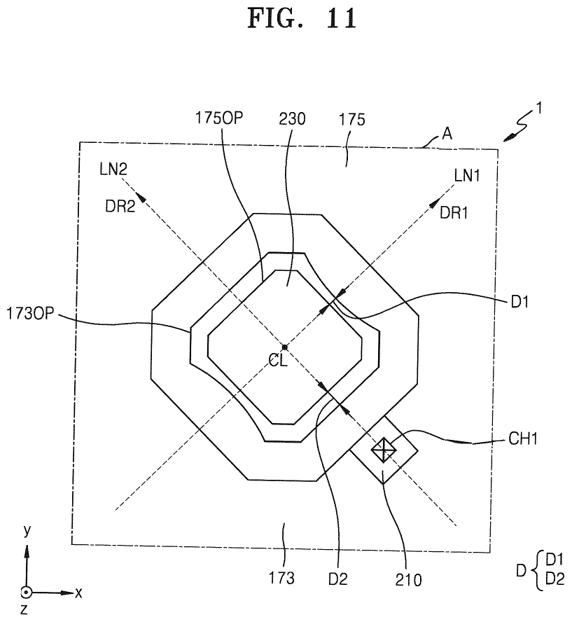

FIG. 11 is a schematic plan view of the display device 1 according to some embodiments.

Particularly, FIG. 11 is an enlarged view of region A of FIG. 1.

In FIG. 11, the reference numbers that are the same as those of FIGS. 4 and 5 refer to the same members, and thus are omitted.

As shown in FIG. 11, in a plan view, the pixel opening 175OP may have a rectangular shape. In this case, the edge of the pixel opening 175OP may be chamfered and/or rounded. In a plan view, an angle between the first line LN1 and the second line LN2 may be 90 degrees. For example, in a plan view, the first line LN1 may penetrate the center of a side of the pixel opening 175OP. In a plan view, the second line LN2 may penetrate through a center of a side of the pixel opening 175OP.

In the cross-section of the display device 1 taken along the first line LN1, the intermediate opening 173OP and the pixel opening 175OP may be spaced apart from each other by a first distance D1. That is, in a cross-section of the display device 1 taken along the first line LN1, the first distance D1 may be a distance between the end of the intermediate insulating layer 173 defining the intermediate opening 173OP and the end of the bank layer 175 defining the pixel opening 175OP.

In the cross-section of the display device 1 taken along the second line LN2, the intermediate opening 173OP and the pixel opening 175OP may be spaced apart from each other by the second distance D2. That is, in the cross-section of the display device 1 taken along the second line LN2, the second distance D2 may be a distance between the end of the intermediate insulating layer 173 defining the intermediate opening 173OP and the end of the bank layer 175 defining the pixel opening 175OP. In this case, the first distance D1 may be different from the second distance D2. For example, the second distance D2 may be greater than the first distance D1.

The distance between the intermediate opening 173OP and the pixel opening 175OP may be defined as the first separation distance D. In a plan view shown in FIG. 11, the first separation distance D between the intermediate opening 173OP and the pixel opening 175OP may be changed continuously along the circumference of the pixel opening 175OP. In a plan view, the second distance D2, which is the first separation distance D along the second line LN2, may be greater than the first distance D1, which is the first separation distance D along the first line LN1. In this case, in a plan view, the first separation distance D may include continuously increasing sections from the first distance D1 to the second distance D2, along the circumference of the pixel opening 175OP.

In this case, in a plan view, the intermediate opening 173OP may include a concave portion. That is, in a plan view, at least a portion of the intermediate opening 173OP may be concave with respect to a direction moving radially away from the center line CL. The end of the intermediate insulating layer 173 defining the intermediate opening 173OP may include a convex portion. In a plan view, with respect to a direction toward the center line CL from the outside, at least a portion of the end of the intermediate insulating layer 173 may be convex.

According to some embodiments, the emission efficiency of the display device may be relatively improved.

The effects of the disclosure are not limited to the effects mentioned above, and other effects that are not mentioned can be clearly understood by those of ordinary skills in the art from the description of the claim.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of embodiments according to the present disclosure as defined by the following claims, and their equivalents.

What is claimed is:

1. A display device comprising:
a substrate;
an intermediate insulating layer on the substrate and comprising an intermediate opening;
a pixel electrode on the intermediate insulating layer such that at least a portion of the pixel electrode is accommodated in the intermediate opening; and
a bank layer on the pixel electrode and comprising a pixel opening overlapping the intermediate opening, wherein,
in a cross-section taken along a first line extending in a first direction, the intermediate opening and the pixel opening are spaced apart from each other by a first distance,
in a cross-section taken along a second line extending in a second direction crossing the first direction, the intermediate opening and the pixel opening are spaced apart from each other by a second distance, and
the first distance is different from the second distance.

2. The display device of claim 1, wherein a distance between the intermediate opening and the pixel opening changes continuously along a circumference of the pixel opening.

3. The display device of claim 2, wherein, in a plan view, the intermediate opening comprises a convex portion.

4. The display device of claim 2, wherein, in a plan view, the intermediate opening includes a concave portion.

5. The display device of claim 1, wherein, in a plan view, an end of the intermediate insulating layer defining the intermediate opening is inclined.

6. The display device of claim 5, wherein,
in a cross-section view taken along the first line, the end of the intermediate insulating layer defining the intermediate opening is inclined by a first angle,
in a cross-section view taken along the second line, the end of the intermediate insulating layer defining the intermediate opening is inclined by a second angle, and
the first angle is different from the second angle.

7. The display device of claim 6, wherein
the second distance is greater than the first distance, and
the first angle is greater than the second angle.

8. The display device of claim 1, wherein, in a plan view, an angle between the first line and the second line is 45 degrees.

9. The display device of claim 1, wherein, in a plan view, an angle between the first line and the second line is 90 degrees.

10. The display device of claim 1, further comprising:
an emission layer on the bank layer to be accommodated in the pixel opening; and
a common electrode on the bank layer to cover the emission layer.

11. An electronic device comprising:
a substrate;
an intermediate insulating layer on the substrate and comprising an intermediate opening;
a pixel electrode on the intermediate insulating layer such that at least a portion of the pixel electrode is arranged in the intermediate opening; and
a bank layer on the pixel electrode and comprising a pixel opening overlapping the intermediate opening, wherein,
in a cross-section taken along a first line extending in a first direction, an end of the intermediate insulating layer defining the intermediate opening is inclined by a first angle,
in a cross-section taken along a second line extending in a second direction crossing the first direction, the end of the intermediate insulating layer defining the intermediate opening is inclined by a second angle, and
the first angle is different from the second angle.

12. The electronic device of claim 11, wherein,
in a cross-section taken along the first line, the intermediate opening and the pixel opening are spaced apart from each other by a first distance,
in a cross-section taken along the second line, the intermediate opening and the pixel opening are spaced apart from each other by a second distance, and
the first distance is different from the second distance.

13. The electronic device of claim 12, wherein a distance between the intermediate opening and the pixel opening changes continuously along a circumference of the pixel opening.

14. The electronic device of claim 13, wherein, in a plan view, the intermediate opening comprises a convex portion.

15. The electronic device of claim 13, wherein the intermediate opening includes a concave portion.

16. The electronic device of claim 12, wherein
the second distance is greater than the first distance, and
the first angle is greater than the second angle.

17. The electronic device of claim 11, wherein, in a plan view, an angle between the first line and the second line is 45 degrees.

18. The electronic device of claim 11, wherein, in a plan view, an angle between the first line and the second line is 90 degrees.

19. The electronic device of claim 11, further comprising:
an emission layer on the bank layer to be accommodated in the pixel opening; and
a common electrode on the bank layer to cover the emission layer.

20. The electronic device of claim 11, wherein a width of the intermediate opening is greater than a width of the pixel opening.
